(19) United States
(12) Patent Application Publication
(10) Pub. No.: US 2012/0024350 A1
(43) Pub. Date: Feb. 2, 2012

(54) Photovoltaic module frame and a photovoltaic module having the frame

(75) Inventors: Palvin Chee Leong Chan, Seattle, WA (US); Lizhong Wu, Wuxi (CN); Xili Jiao, Wuxi (CN)

(73) Assignee: WUXI SUNTECH POWER CO., LTD., Wuxi (CN)

(21) Appl. No.: 13/137,269

(22) Filed: Aug. 2, 2011

(30) Foreign Application Priority Data
Aug. 2, 2010 (CN) 201020278620.9

(51) Int. Cl. H01L 31/048

(52) U.S. Cl. 136/251

(57) ABSTRACT

This invention discloses a photovoltaic module comprising a photovoltaic module panel and a plurality of photovoltaic module frame segments adapted for holding the photovoltaic module therein; each of the photovoltaic module frame segments comprises a base wall, a photovoltaic module holding part and a first side wall extending between the base wall and the photovoltaic module holding part; the photovoltaic module holding part has a recess facing toward a first direction, the photovoltaic module holding part defines an upper face and a bottom face opposite to each other, wherein said first side wall is oriented at an obtuse angle relative to the bottom face of the photovoltaic module holding part. The advantageous effects of this invention are: the simple structure and the unique configuration of the frame can realize the stable stacking and the fast and stable assembly of the photovoltaic modules and improve the space efficiency when packaging and transporting, thereby reducing the packaging and transporting costs.

### CROSS-REFERENCE TO RELATED APPLICATIONS

This application claims priority to Chinese Patent Application No. 201020278620.9 entitled “Photovoltaic Module Frame and Photovoltaic Module Having the Frame,” filed on Aug. 2, 2010, the disclosure of which is hereby incorporated by reference in its entirety.

### TECHNICAL FIELD

This invention relates to the photovoltaic field, particularly to a photovoltaic module frame and a photovoltaic module having the frame.

### PRIOR ARTS

Packaging is a key step in producing a photovoltaic (PV) module. Mounting frames is a crucial procedure in the packaging process and performs the functions of reinforcing the PV module, further sealing the PV module and extending the service life thereof. More significantly, a PV module can be fixed on other members, such as a wall of a building, a roof, a system installation rack, etc. by mounting PV module frames at the sides of the PV module.

The Chinese patent application with the authorization date of Apr. 18, 2007 and the patent number of 200520140581.5 provides a large-scale PV module frame having a gel receiving groove, as shown in FIG. 1. With reference to FIG. 1, the PV module frame comprises a module recess 1′, a sidewall 2′ and a base wall 3′, wherein the module recess 1′ comprises an upper face 11′ and a bottom face 12′ and a side face 13′, the sidewall 2′ extends between the base wall 3′ and the module recess 1′, and the base wall 3′ extends from an end of the sidewall 2′ along the same direction of the groove opening of the module recess 1′. The module recess 1′ is a wedged gel receiving groove with a bigger groove bottom and a smaller groove opening. A PV module 5′ is held by the module recess 1′.

The frame of the prior art at least has the following problems: in the process of manufacturing, packaging and transporting the PV module having the frame, when a plurality of PV modules are stacked, the frame of the prior art may not be suitable for the special PV module panels with the result of being collapsed; when a plurality of PV modules are stacked, the frame of the upper PV module is prone to scratch the surface of the lower PV module under it; the PV modules occupy too much space in transporting, which increases the transportation cost of the PV module.

### DETAILED DESCRIPTION OF THE INVENTION

The objective of this invention is to provide a PV module frame and a PV module having the frame. By using the frame, the PV modules can be stacked steadily and the production, packaging and transportation costs of the PV modules can be reduced.

To solve the above technical problems, this invention provides a photovoltaic module, comprising a photovoltaic module panel and a plurality of photovoltaic module frame segments adapted for holding the photovoltaic module panel therein, each of the photovoltaic module frame segments comprising a base wall, a photovoltaic module holding part and a first side wall extending between the base wall and the photovoltaic module holding part, the photovoltaic module holding part having a recess facing toward a first direction, the photovoltaic module holding part defining an upper face and a bottom face opposite to each other, wherein said first side wall is oriented at an obtuse angle relative to the bottom face of the photovoltaic module holding part.

Preferably, the base wall is configured to extend from an end of the first side wall in a second direction opposite to said first direction.

Preferably, said photovoltaic module frame is provided with below said bottom face a stacking platform adapted for stacking on another photovoltaic module frame.

Further preferably, the stacking platform has a bottom surface disposed in parallel with said bottom face of the photovoltaic module holding part.

Further preferably, the stacking platform is of cavity structure.

Further preferably, the bottom surface of the stacking platform extends inwards and exceeds an inside wall of the cavity of the stacking platform.

Further preferably, a portion, which is located below the bottom face of the photovoltaic module holding part, of the first side wall, is of cavity structure.

Further preferably, adjacent frame segments are connected by an angle connection plate having a first plate part and a second plate part integral with each other, wherein the first plate part and the second plate part are respectively inserted into the cavities of the stacking platforms of the corresponding frame segments.

Further preferably, a surface of the angle connection plate is provided with fringes. Preferably, at least one of the two frame segments adapted for holding opposing sides of the photovoltaic module panel further comprises a second side wall extending upwards from a free end of the base wall, wherein an angle defined between the second side wall and the base wall is equal to the obtuse angle between the first side wall and the bottom face of the photovoltaic module holding part.

This invention further provides a photovoltaic module, comprising a photovoltaic module panel and a plurality of photovoltaic module frame segments adapted for holding the photovoltaic module panel therein, each of the photovoltaic module frame segments comprising a base wall, a photovoltaic module holding part and a first side wall extending between the base wall and the photovoltaic module holding part, said photovoltaic module holding part and said base wall configured to located at opposite sides relative to the first side wall.

Preferably, said photovoltaic module holding part defines an upper face and a bottom face opposite to each other, wherein said first side wall and said bottom face defines therebetween an obtuse angle disposed adjacent to the photovoltaic module holding part.

Preferably, the photovoltaic module holding part defines a recess facing toward a first direction while the base wall is configured to extending from the first side wall in a second direction opposite to the first direction.

Preferably, at least one of the two frame segments adapted for holding opposing sides of the photovoltaic module panel further comprises a second side wall extending upwards from a free end of the base wall, wherein an angle defined between the second side wall and the base wall is equal to the obtuse angle between the first side wall and the bottom face of the photovoltaic module holding part.

This invention further provides a photovoltaic module frame adapted for holding a photovoltaic module therein, comprising a base wall, a photovoltaic module holding part and a first side wall extending between the base wall and the photovoltaic module holding part, said photovoltaic module holding part and said base wall configured to located at opposite sides relative to the first side wall.

Preferably, said photovoltaic module holding part defines an upper face and a bottom face opposite to each other, wherein said first side wall is oriented at an obtuse angle relative to the bottom face of the photovoltaic module holding part.

Preferably, the photovoltaic module holding part defines a recess facing toward a first direction while the base wall is configured to extending from the first side wall in a second direction opposite to the first direction.

Preferably, the photovoltaic module frame comprises a second side wall extending upwards from a free end of the base wall, wherein an angle defined between the second side wall and the base wall is equal to the obtuse angle between the first side wall and the bottom face of the photovoltaic module holding part.

This invention at least has the following advantageous effects: the simple structure of the frame can realize the stable stacking of the PV modules and improve the space efficiency when packaging and transporting, thereby reducing the packaging and transporting costs of the PV modules; specifically, compared with other types of frames, more PV modules can be received in the same space (such as a packaging box); the unique configuration of the frame can realize the fast and stable assembly of the PV modules; in addition, when being stacked, the frame of the upper PV module will not scratch the surface of lower the PV module under it.

### EXPLANATIONS OF THE DRAWINGS

FIG. 1 is a schematic sectional view of the frame of a PV module of the prior art;

FIG. 2 is a schematic sectional view of the frame of the PV module of one embodiment of this invention;

FIGS. 3-7 are schematic sectional views of the frames of the PV modules of other selective embodiments of this invention;

FIG. 8 is a schematic view of the frames of adjacent PV modules fitted over each other when the PV system is installed;

FIG. 9 is a schematic drawing of a PV module with its four sides mounted with frames, and this figure also shows a schematic drawing of an angle connection plate;

FIG. 10 is a schematic sectional view of a plurality of stacked PV modules cut along the direction in parallel with the short line side of the PV module; and

FIG. 11 is a schematic sectional view of a plurality of stacked PV modules cut along the direction in parallel with the long line side of the PV module.

### MAIN REFERENCE SIGNS

1 Recess
2 First side wall
3 Stacking platform
4 Base wall
5 Second side wall
6 Angle connection plate

### MODE FOR CARRYING OUT THE INVENTION

The followings will describe this invention in detail with reference to the drawings and the embodiments.

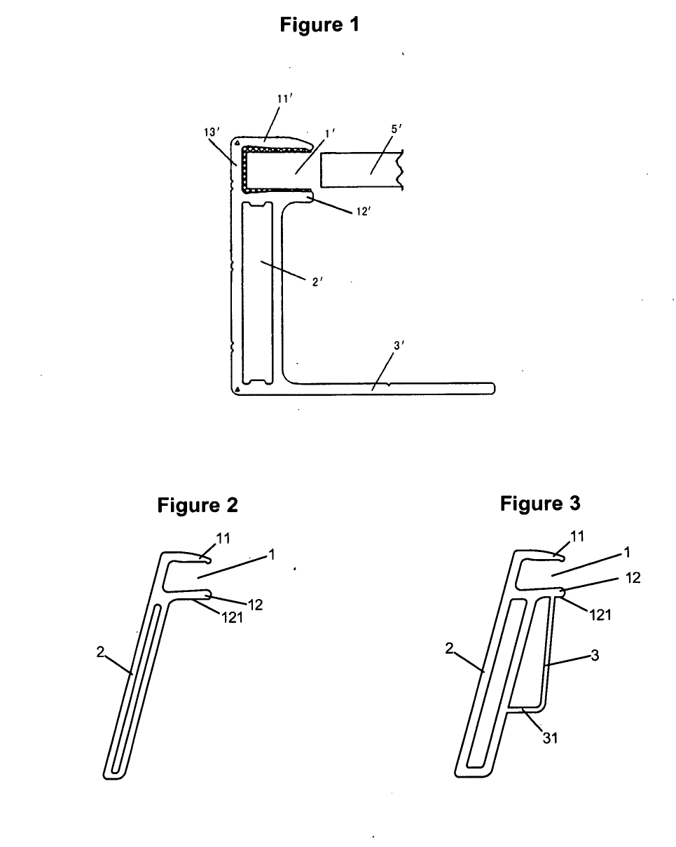

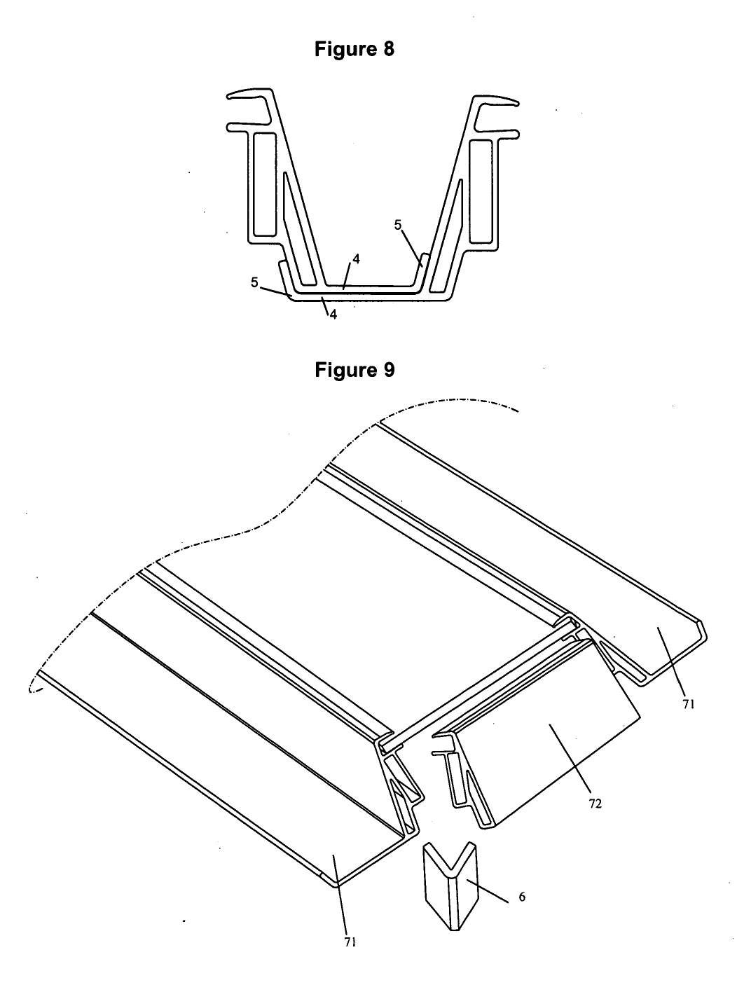

FIG. 2 is a schematic sectional view of a photovoltaic (PV) module frame of one embodiment of this invention. As shown in FIG. 2 and FIGS. 7-8, the PV module frame comprises a base wall 4, a PV module holding part and a first side wall 2 integrally extending between the base wall 4 and the photovoltaic module holding part, wherein the PV module holding part has a recess 1 facing toward a first direction and defines an upper face 11 and a bottom face 12 opposite to each other. The first side wall 2 integrally extends from the bottom face 12 of the PV module holding part, and is oriented at an obtuse angle relative to the bottom face 12. More specifically, the first side wall 2 integrally extends from the bottom surface 121 of the PV module holding part, and is oriented at an obtuse angle relative to the bottom surface 121. Comparing with FIG. 1 of the prior art, it can be seen in FIGS. 7-8 of the embodiment of this invention that the major improvement of the PV module frame of this invention over that of the prior art is that the first side wall is oriented at an obtuse angle relative to the bottom face 12 of the PV module holding part. In other words, said photovoltaic module holding part and said base wall 4 are configured to located at opposite sides relative to the first side wall 2. Such embedded stacking of a plurality of PV modules having the PV module frames can be easily realized (see FIGS. 10-11), thereby preventing a plurality of stacked PV modules from collapsing. In addition, the space efficiency can be improved when packaging and transporting the PV modules, thereby reducing the packaging and transporting costs of the PV modules; specifically, compared with other types of PV module frames, more PV modules can be received in the same space (such as a packaging box).

In addition, as shown in FIG. 2, a portion, which is located below the bottom face 12 of the PV module holding part, of the first side wall 2, is of cavity structure.

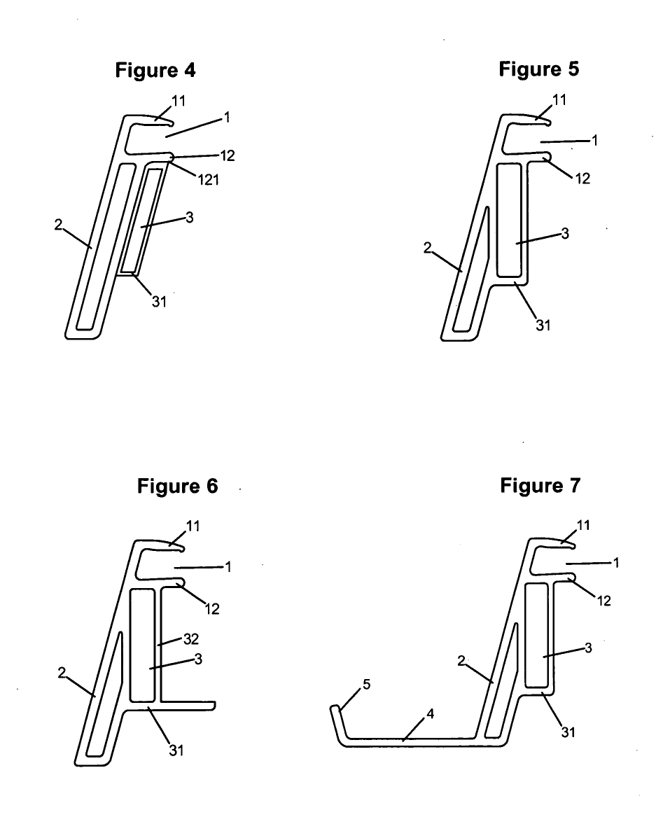

FIGS. 3-6 are schematic sectional views of the PV module frames of the PV modules of other selective embodiments of this invention. As shown in these figures, the PV module frame is provided with below the bottom face 12 a stacking platform 3 adapted for stacking on another PV module frame. When the modules are stacked, the stacking platform 3 has a bottom surface 31 disposed in parallel with the bottom face 12 of the PV module holding part. The stacking platform 3 may adopt various structures shown in FIGS. 3-6. The stacking platform 3 may have a cavity. A shown in FIG. 6, the bottom surface 31 of the stacking platform 3 extends inwards and exceeds an inside wall 32 of the cavity of the stacking platform 3, so that, when modules are stacked, the contacting area between adjacent modules can be increased, thereby improving the stacking stability.

FIG. 7 is a schematic sectional view of the PV module frame of the PV module of another selective embodiment of this invention. As shown in this figure, the PV module frame comprises a base wall 4 that is configured to integrally extend from an end of the first side wall 2 in a second direction opposite to the first direction. In addition, the PV module frame may further comprise a second side wall 5 extending upwards from a free end of the base wall 4, wherein an angle defined between the second side wall 5 and the base wall 4 is equal to the obtuse angle between the first side wall 2 and the bottom face 12 of the PV module holding part. It should be noted that the PV module frame shown in FIG. 7 is an improved PV module frame of the one shown in FIG. 5. However, it should be understood that such improvement can be applied to any of the PV module frames shown in FIGS. 2-6. In the case that a base wall 4 and a second side wall 5 are provided, when installed in a PV system, the PV module can be fitted over one another as shown in FIG. 8, which helps the fast and stable fixing and connecting between the adjacent PV modules.

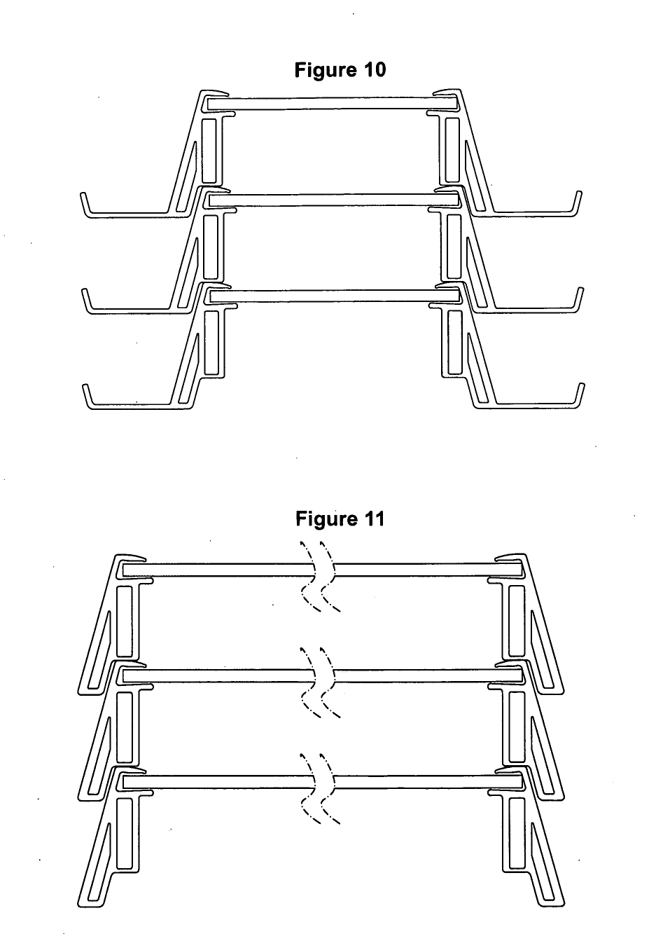

This invention also discloses a PV module comprising a PV module panel and a plurality of PV module frame segments adapted for holding the PV module panel therein, the PV module has four sides in the selective embodiment. As shown in FIG. 9, the PV module frame segments 72 (the PV module frame segments 72 shown in this figure is yet to be installed) mounted at the opposite short line sides of the PV module, i.e. the first and third sides, may be any one of the PV module frames shown in FIGS. 2-6; and the PV module frame segments 71 mounted at the opposite long line sides of the PV module, i.e. the second and fourth sides, may be the PV module frame shown in FIG. 7. Preferably, as shown in FIG. 9, at least one of the two PV module frame segments 71 at opposing sides includes a second side wall 5. In addition, in this PV module, adjacent PV module frame segments 71 and/or 72 are connected by an angle connection plate 6. As shown in FIG. 9, the angle connection plate 6 has a first plate part and a second plate part integral with each other, wherein the first plate part and the second plate part are respectively inserted into the cavities of the stacking platforms of the corresponding PV module frame segments. The angle connection plate 6 may be in a substantially L or V shape. In addition, a surface of the angle connection plate 6 may be provided with fringes (not shown) to reinforce the connection.

FIGS. 10 and 11 are schematic sectional views of a plurality of stacked PV modules respectively cut along the direction in parallel with the short line side and the long line side of the PV module, and respectively show the stacked state of the PV module frames 71 at the second and fourth sides and the PV module frames 72 at the first and third sides of the PV module.

The above are only part of the preferable embodiments of this invention and are not intended to limit this invention. Equivalent modifications made according to the claims of this invention shall be deemed within the protection scope of this invention.

1. A photovoltaic module, comprising: a photovoltaic module panel and a plurality of photovoltaic module frame segments adapted for holding the photovoltaic module panel therein, each of the photovoltaic module frame segments comprising a base wall, a photovoltaic module holding part and a first side wall extending between the base wall and the photovoltaic module holding part, the photovoltaic module holding part having a recess facing toward a first horizontal direction, the photovoltaic module holding part defining an upper face and a bottom face opposite to each other, wherein said first side wall is oriented at an obtuse angle relative to the bottom face of the photovoltaic module holding part.

2. The photovoltaic module according to claim 1, wherein the base wall is configured to extend from an end of the first side wall in a second direction opposite to said first horizontal direction.

3. The photovoltaic module according to claim 2, wherein the base wall is disposed parallel to said first horizontal direction.

4. The photovoltaic module according to claim 1, wherein said photovoltaic module frame is provided with below said bottom face a stacking platform adapted for stacking on another photovoltaic module frame.

5. The photovoltaic module according to claim 4, wherein the stacking platform has a bottom surface disposed in parallel with said bottom face of the photovoltaic module holding part.

6. The photovoltaic module according to claim 4, wherein the stacking platform is of cavity structure.

7. The photovoltaic module according to claim 6, wherein the bottom surface of the stacking platform extends inwards and exceeds an inside wall of the cavity of the stacking platform.

8. The photovoltaic module according to claim 6, wherein a portion, which is located below the bottom face of the photovoltaic module holding part, of the first side wall, is of cavity structure.

9. The photovoltaic module according to claim 6, wherein adjacent frame segments are connected by an angle connection plate having a first plate part and a second plate part integral with each other, wherein the first plate part and the second plate part are respectively inserted into the cavities of the stacking platforms of the corresponding frame segments.

10. The photovoltaic module according to claim 9, wherein a surface of the angle connection plate is provided with fringes.

11. The photovoltaic module according to claim 1, at least one of the two frame segments adapted for holding opposing sides of the photovoltaic module panel further comprises a second side wall extending upwards from a free end of the base wall, wherein an angle defined between the second side wall and the base wall is equal to the obtuse angle between the first side wall and the bottom face of the photovoltaic module holding part.

12. A photovoltaic module, comprising: a photovoltaic module panel and a plurality of photovoltaic module frame segments adapted for holding the photovoltaic module panel therein, each of the photovoltaic module frame segments comprising a base wall, a photovoltaic module holding part and a first side wall integrally extending between the base wall and the photovoltaic module holding part, said photovoltaic module holding part and said base wall configured to located at opposite sides relative to the first side wall.

13. The photovoltaic module according to claim 12, wherein said photovoltaic module holding part defines an upper face and a bottom face opposite to each other, wherein said first side wall and said bottom face defines therebetween an obtuse angle disposed adjacent to the photovoltaic module holding part.

14. The photovoltaic module according to claim 12, wherein the photovoltaic module holding part defines a recess facing toward a first direction while the base wall is configured to extending from the first side wall in a second direction opposite to the first direction.

15. The photovoltaic module according to claim 12, at least one of the two frame segments adapted for holding opposing sides of the photovoltaic module panel further comprises a second side wall extending upwards from a free end of the base wall, wherein an angle defined between the second side wall and the base wall is equal to the obtuse angle between the first side wall and the bottom face of the photovoltaic module holding part.

16. A photovoltaic module frame adapted for holding a photovoltaic module panel therein, comprising: a base wall, a photovoltaic module holding part and a first side wall extending between the base wall and the photovoltaic module holding part, said photovoltaic module holding part and said base wall configured to located at opposite sides relative to the first side wall.

17. The photovoltaic module frame according to claim 16, wherein said photovoltaic module holding part defines an upper face and a bottom face opposite to each other, wherein said first side wall is oriented at an obtuse angle relative to the bottom face of the photovoltaic module holding part.

18. The photovoltaic module frame according to claim 16, wherein the photovoltaic module holding part defines a recess facing toward a first direction while the base wall is configured to extending from the first side wall in a second direction opposite to the first direction.

19. The photovoltaic module frame according to claim 16, the photovoltaic module frame comprises a second side wall extending upwards from a free end of the base wall, wherein an angle defined between the second side wall and the base wall is equal to the obtuse angle between the first side wall and the bottom face of the photovoltaic module holding part.
